(19) United States
(12) Patent Application Publication
(10) Pub. No.: US 2009/0108305 A1
(43) Pub. Date: Apr. 30, 2009

(54) SEMICONDUCTOR HAVING A CORNER COMPENSATION FEATURE AND METHOD

(76) Inventors: Lionel J. Riviere-Cazaux, Austin, TX (US); Matthew A. Thompson, Round Rock, TX (US)

Correspondence Address: FREESCALE SEMICONDUCTOR, INC.;LAW DEPARTMENT, 7700 WEST PARMER LANE MD:TX32/PL02, AUSTIN, TX, 78729, US

(21) Appl. No.: 11/927,962

(22) Filed: Oct. 30, 2007

(51) Int. Cl. H01L 29/78; H01L 21/336

(52) U.S. Cl. 257/288; 438/197; 257/E29.255; 257/E21.409

(57) ABSTRACT

A semiconductor device includes an active semiconductor material. A transistor gate overlies a first portion of the active semiconductor material. A second portion intersects the first portion at a corner which is distorted during manufacture resulting in rounding of the corner. The active semiconductor material extends into the corner to create a concave corner. To reduce the corner rounding, a compensation feature extends from a first edge of the first portion by an amount less than needed to provide an electrical contact structure on the compensation feature. The feature is positioned laterally further away from the corner than the overlying transistor gate. The compensation feature is positioned from the corner by a dimension that is within 0.4 to 0.6 of the wavelength of light used to image features of the semiconductor device. Due to optical distortion the compensation feature itself has a nonlinear shape.

### BACKGROUND

1. Field

This disclosure relates generally to semiconductors, and more specifically, to semiconductors having a corner compensation feature and method.

2. Related Art

With respect to Metal Oxide Semiconductor (MOS) transistor devices, the presence of a corner in a transistor body undesirably modifies the MOS transistor effective width (W_{eff}). That is, the presence of the corner in the transistor body introduces variability in W_{eff} and thus contributes to undesirable errors in the transistor behaviour modeling.

Optical proximity compensation (OPC) methods are known. OPC creates “virtual” mask shapes in order to compensate for corner rounding in a transistor body. However, these OPC methods are constrained by the fact that these virtual shapes do not print on the target semiconductor material. This limits the effectiveness of the OPC methods.

Accordingly, there is a need for an improved method and apparatus for overcoming the problems in the art as discussed above.

### BRIEF DESCRIPTION OF THE DRAWINGS

The present invention is illustrated by way of example and is not limited by the accompanying figures, in which like references indicate similar elements. Elements in the figures are illustrated for simplicity and clarity and have not necessarily been drawn to scale.

FIG. 1 is a layout design view of an ideal MOS transistor device including a well defined inside corner of active semiconductor material of a transistor body;

FIG. 2 is a fabricated layout view of a MOS transistor device according to the prior art including a rounded inside corner of active semiconductor material of a transistor body;

FIG. 3 is a layout design view of a MOS transistor device including a compensation feature of active semiconductor material of a transistor body according to one embodiment of the present disclosure;

FIG. 4 is a photomask instantiation of the MOS transistor device layout design view of FIG. 3 including a compensation feature of active semiconductor material of a transistor body according to one embodiment of the present disclosure;

FIG. 5 is a fabricated layout view of a MOS transistor device including a compensation feature of active semiconductor material of a transistor body according to one embodiment of the present disclosure; and

FIG. 6 is a fabricated layout view of a MOS transistor device including a compensation feature of active semiconductor material of a transistor body illustrating rounded corners formed with first and second focus and exposure settings according to the embodiments of the present disclosure.

### DETAILED DESCRIPTION

According to one embodiment of the present disclosure, a compensation feature is created directly in the semiconductor material of a transistor body, wherein the compensation feature substantially limits the undesirable effect of corner rounding. While the compensation feature shape actually prints on the target semiconductor material, the compensation feature does not necessarily contribute to the corresponding transistor's behavior.

In connection with the compensation feature according to the embodiments of the present disclosure, optical interference between the transistor body corner and the compensation feature results in a constructive interference, which leads to better control of corner rounding in the transistor body after lithographic print. The compensation feature is used to achieve an improved control of the transistor effective width (W_{eff}). In addition, the compensation feature enables the obtaining of a smaller space between a corresponding corner and its adjacent gate. Accordingly, for a larger corner shape, the compensation feature according to the embodiments of the present disclosure provides a less process sensitive transistor configuration.

In one example of MOS transistor devices, flipflop cells have many narrow transistor bodies with corners. The compensation feature according to the embodiments of the present disclosure advantageously limits variability on these sensitive cells.

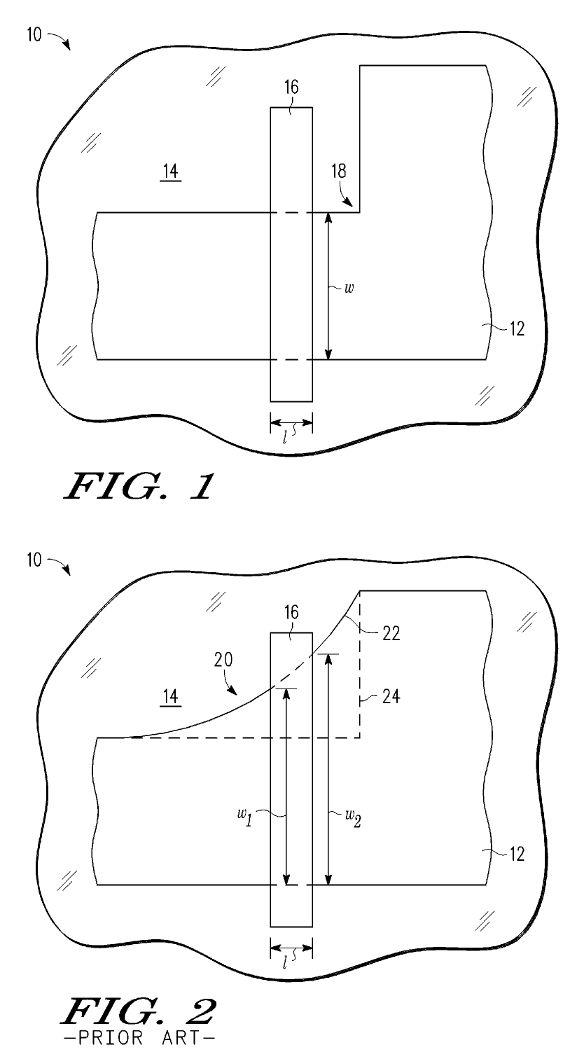

FIG. 1 is a layout design view of an ideal MOS transistor device 10 including a well defined inside corner of active semiconductor material of a transistor body. In particular, device 10 includes an active semiconductor material transistor body 12 with isolation region 14 disposed about outer boundaries of the transistor body 12. Isolation region 14 can comprise, for example, a shallow trench isolation region, as is known in the art. A transistor control electrode 16 is disposed overlying a portion of the active semiconductor material 12, wherein a suitable dielectric (not shown) is disposed in-between the control electrode and the underlying portion of the active semiconductor material. Control electrode 16 can also be referred to as a gate electrode or gate. Control electrode 16 is further characterized by a length dimension (l) and an active semiconductor width dimension (w). Note that in the ideal transistor, the width dimension (w) of the transistor body 12 is constant across the length of the transistor body in the region directly underlying the control electrode 16. Thus for the ideal transistor, the transistor effective width (W_{eff}) is constant. Furthermore, the active semiconductor material is characterized by a well defined corner 18.

FIG. 2 is a fabricated layout view of a MOS transistor device 11 according to the prior art including a rounded inside corner of active semiconductor material of a transistor body. In particular, device 11 includes an active semiconductor material transistor body 13 with isolation region 14 disposed about outer boundaries of the active semiconductor material transistor body 13. Isolation region 14 can comprise, for example, a shallow trench isolation region, as is known in the art. A transistor control electrode 16 is disposed overlying a portion of the active semiconductor material 13, wherein a suitable dielectric (not shown) is disposed in-between the control electrode and the underlying portion of the active semiconductor material.

In FIG. 2, control electrode 16 is further characterized by a length dimension (l) and various active semiconductor width dimensions, extending from a first width dimension (w1) to a second width dimension (w2). In other words, in the prior art transistor, the width dimension of the transistor body is not constant across the length of the transistor body directly underlying the control electrode, but varies from the first width dimension (w1) to the second width dimension (w2) from a first edge of the control electrode 16 to a second edge of the control electrode. Thus, for the prior art transistor, the transistor effective width (W_{eff}) is not constant and varies undesirably. In addition, the variation in transistor effective width (W_{eff}) can be further exaggerated in that the location of the control electrode 16 may vary from that as illustrated. That is, the location of the control electrode 16 can be located slightly to the left or to the right from that as illustrated. Variation of the location of the control electrode can occur due to variations in optical alignment during a corresponding patterning step for the control electrode, and thereby influencing variations in width dimensions w1 and w2.

The active semiconductor material transistor body 13 is also characterized by a rounded corner 20. Rounded corner 20 includes a contour 22. Contour 22 of rounded corner 20 establishes minimum and maximum gate widths corresponding to the first width dimension (w1) and the second width dimension (w2), respectively. In addition, as a result of the rounded corner 20, additional active semiconductor material 24 is present within the active semiconductor material transistor body 13.

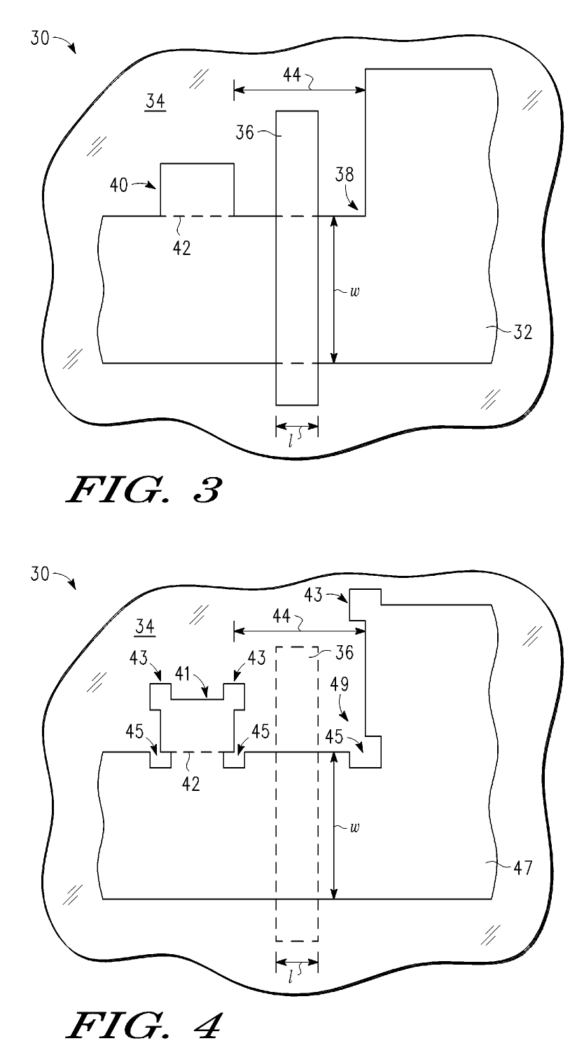

FIG. 3 is a layout design view of a MOS transistor device 30 including a compensation feature of active semiconductor material of a transistor body according to one embodiment of the present disclosure. In particular, device 30 includes an active semiconductor material transistor body 32 with isolation region 34 disposed about outer boundaries of the active semiconductor material of transistor body 32. The area of active semiconductor material of transistor body 32 comprises a first portion 33 with a first edge 35 and a second portion 37 with a second edge 39, the first edge 35 and the second edge 39 intersecting at a desired right angle to form a well defined corner 38. Isolation region 34 can comprise, for example, a shallow trench isolation region, as is known in the art.

A transistor control electrode 36 is disposed overlying a portion of the active semiconductor material of transistor body 32, wherein a suitable dielectric (not shown) is disposed in-between the control electrode and the underlying portion of the active semiconductor material. Control electrode 36 can also be referred to as a gate electrode or gate. Control electrode 36 is further characterized by a length dimension (l) and an active semiconductor width dimension (w). In other words, the transistor control electrode overlies the first portion 33 of the area of active semiconductor material and comprises a major dimension including a major axis that is perpendicular to the first edge 35 of the first portion 33 of the area of active semiconductor material and comprises a minor dimension including a minor axis that is perpendicular to the second portion 37 of the area of active semiconductor material.

The layout design view of the MOS transistor device 30 further includes a compensation feature 40 coupled to a portion of the active semiconductor material of transistor body 32 at a merged boundary 42. The compensation feature 40 is spaced from the corner 38 by an amount indicated by reference numeral 44. In one embodiment, spacing 44 corresponds to a distance of (0.4)λ to (0.6)λ, wherein Aλ the wavelength of the optical lithography used in printing the pattern onto the active semiconductor in the formation of the transistor body. Note that in the design layout of the transistor, the width dimension (w) of the transistor body is constant across the length of the transistor body that directly underlies the control electrode. Thus for the layout view of the transistor device 30, the transistor effective width (W_{eff}) is constant. Furthermore, the active semiconductor material is characterized by a well defined corner 38.

In other words, the compensation feature 40 extends from the first edge 35 of the first portion 33 of the area of active semiconductor material less than an amount to provide an electrical contact structure on the compensation feature and positioned laterally further away from the corner 38 than the overlying transistor control electrode 36, the compensation feature 40 being positioned from the corner by a dimension 44 that is within 0.4 to 0.6 of the wavelength of light used to image features of the semiconductor device.

FIG. 4 is a photomask instantiation of the MOS transistor device layout of FIG. 3 including a corner compensation feature of active semiconductor material of a transistor body according to one embodiment of the present disclosure. In particular, photomask instantiation 31 includes an active semiconductor material instantiation of transistor body 47. The photomask instantiation 31 does not include a control electrode, however, a control electrode 36 is illustrated in dashed lines as being disposed overlying a portion of the active semiconductor material instantiation of transistor body 47. As mentioned above, control electrode 36 is further characterized by a length dimension (l) and an active semiconductor width dimension (w). Note that in the instantiation 31, the width dimension (w) of the transistor body is constant across the length of the transistor body in the region directly underlying the control electrode. Thus for the photomask instantiation of the MOS transistor device layout view, the transistor effective width (W_{eff}) is constant.

Furthermore, the active semiconductor material instantiation is characterized by a corner instantiation, as is generally indicated by reference numeral 49. The photomask instantiation view 31 further includes a corner compensation feature instantiation 41 coupled to a portion of the instantiation of active semiconductor material of transistor body 47 at a merged boundary 42. The corner compensation feature instantiation 41 is substantially spaced from the corner 49 by an amount indicated by reference numeral 44. As discussed above, spacing 44 corresponds to a distance of (0.4)λ to (0.6)λ, wherein λ is the wavelength of the optical lithography used in printing the pattern onto the active semiconductor in the formation of the transistor body.

The instantiation 31 further includes various OPC features including serifs 43 and anti-serifs 45. For example, the instantiation of active semiconductor material of transistor body 47 includes a serif 43 located at an outside corner and an anti-serif 45 at the corner 49. In addition, corner compensation feature instantiation 41 includes two serifs 43 located at outer corners of the corner compensation feature instantiation. Likewise, corner compensation feature instantiation 41 includes two anti-serifs 45 located at inner corners where the corner compensation instantiation 41 merges with the instantiation of the semiconductor material of the transistor body 47.

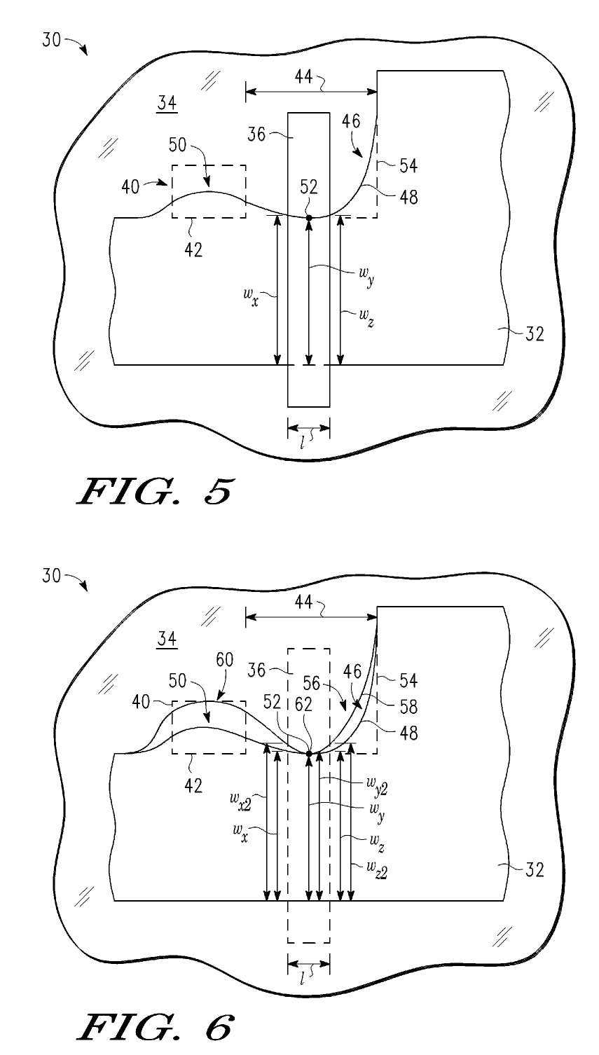

FIG. 5 is a fabricated layout view of a MOS transistor device including a corner compensation feature of active semiconductor material of a transistor body according to one embodiment of the present disclosure. In particular, device 30 includes an active semiconductor material transistor body 32 with isolation region 34 disposed about outer boundaries of the active semiconductor material transistor body 32. Isolation region 34 can comprise, for example, a shallow trench isolation region, as is known in the art. A control electrode 36 is disposed overlying a portion of the active semiconductor material 32, wherein a suitable dielectric (not shown) is disposed in-between the control electrode and the underlying portion of the active semiconductor material.

Control electrode 36 is further characterized by a length dimension (l) and active semiconductor width dimensions (wx, wy, and wz), to be discussed further herein. In addition, the active semiconductor material transistor body 32 is characterized by a rounded corner 46. Furthermore, the fabricated layout view of the MOS transistor device 30 includes a fabricated compensation feature 50. The fabricated compensation feature 50 essentially couples to a portion of the active semiconductor material transistor body 32, for example, at the merged boundary 42 indicated in phantom lines. The layout of the original compensation feature 40 is also shown in phantom lines to illustrate a given transition of the original compensation feature 40 to the fabricated compensation feature 50. The fabricated compensation feature 50 is substantially spaced from the corner by an amount indicated by reference numeral 44.

As indicated above, the active semiconductor material transistor body 32 is characterized by a rounded corner 46. Rounded corner 46 includes a contour 48. Contour 48 of rounded corner 46 establishes minimum and maximum gate widths corresponding to a first width dimension (wx), a second width dimension (wy), and a third width dimension (wz), respectively. As a result of the rounded corner 46, additional active semiconductor material 54 is present within the active semiconductor material transistor body 32.

In one embodiment, the area 54 of active semiconductor material extends into a portion of the corner 46 and underlies the overlying transistor control electrode 36, the active semiconductor material extending from the first edge 35 of the area of active semiconductor material with a contour 48 having less active semiconductor material in an interior portion underlying the control electrode 36 than at an edge boundary underlying the control electrode 36. In addition, the interior portion underlying the control electrode 36 comprising a least amount of active semiconductor material is underlying substantially a middle of the overlying transistor control electrode 36 and along the first edge 35.

In the transistor including the compensation feature according to the embodiments of the present disclosure, the width dimension of the transistor body is not constant across the length of the transistor body directly underlying the control electrode, but varies from the first width dimension (wx), the second width dimension (wy), and the third width dimension (wz) from a first edge of the control electrode 36 to a second edge of the control electrode. However, for the transistor including the compensation feature, while the transistor effective width (W_{eff}) is not constant, the transistor effective width varies less undesirably over the prior art. In addition, the transistor effective width (W_{eff}) is subject to less variation, even though the location of the control electrode 36 may vary from that as illustrated. That is, the location of the control electrode 36 may be located slightly to the left or to the right from that as illustrated. Variation of the location of the control electrode can occur due to variations in optical alignment during a corresponding patterning step for the control electrode, and thereby influencing slight variations in width dimensions wx, wy, and wz. However, according to the embodiments of the present disclosure, the transistor effective width is maintained substantially constant to within a given percentage, wherein the central dimension wy is maintained smaller than either of the outer dimensions wx and wz. Furthermore, contour 48 includes a minimum width point 52 of the active semiconductor material of transistor body 32 in a region underlying gate electrode 36, corresponding to width wy.

In addition, the semiconductor device 30 further includes a source electrode 53 and a drain electrode 57. The source electrode 53 is contained within the active semiconductor material adjacent a first side of the transistor control electrode 36 along the major axis. The drain electrode 57 is contained within the active semiconductor material adjacent a second side of the transistor control electrode 36 along the major axis and that is opposite the first side of the transistor control electrode. Furthermore, the compensation feature 50 is formed as a continuous part of one of the source electrode or the drain electrode within the area of active semiconductor material but does not provide a conduction path for source or drain electrons.

In another embodiment, the compensation feature 50 of the semiconductor device has a nonlinear edge due to optical distortion when forming the compensation feature. A portion 54 of the area of active semiconductor material extends into the corner 46 on either side of the transistor control electrode 36 due to optical distortion, the active semiconductor material increasing in amount on either side of the transistor control electrode 36 as a function of distance from the transistor control electrode.

FIG. 6 is a fabricated layout view of a MOS transistor device including a compensation feature of active semiconductor material of a transistor body illustrating rounded corners formed with first and second focus and exposure settings according to the embodiments of the present disclosure. The fabricated layout view of FIG. 6 is substantially similar to that of FIG. 5 with the following differences. For a first set of lithographic focus and exposure settings, control electrode 36 is characterized by a length dimension (l) and active semiconductor width dimensions (wx, wy, and wz). In addition, for the first set of lithographic focus and exposure settings, the active semiconductor material of the transistor body 32 is characterized by a first rounded corner 46 having a contour 48 and compensation feature 50. Contour 48 includes a minimum width point 52 of the active semiconductor material of transistor body 32 in a region underlying gate electrode 36, corresponding to width Wy.

For a second set of lithographic focus and exposure settings, control electrode 36 is characterized by a length dimension (l) and active semiconductor width dimensions (wx2, wy2, and wz2). In addition, for the second set of lithographic focus and exposure settings, the active semiconductor material of the transistor body 32 is characterized by a second rounded corner 56 having a contour 58 and compensation feature 60. Contour 58 includes a minimum width point 62 of the active semiconductor material of transistor body 32 in a region underlying gate electrode 36, corresponding to width wy2.

Note that even though contours 48 and 58 are different from one another, the difference between minimum width points 52 and 62 of the respective contours is close to zero. That is, the minimum points 52 and 62 are approximately the same due in part because of optical cancellation effects obtained as a result of the first set of lithographic focus and exposure settings and the second set of lithographic focus and exposure settings with corresponding compensation features 50 and 60, respectively.

By now it should be appreciated that there has been provided a semiconductor device that includes an area of active semiconductor material comprising a first portion with a first edge and a second portion with a second edge, the first edge and the second edge intersecting at a desired right angle to form a corner. The semiconductor device also includes an overlying transistor control electrode overlying the first portion of the area of active semiconductor material and comprising a major dimension including a major axis that is perpendicular to the first edge of the first portion of the area of active semiconductor material and comprising a minor dimension including a minor axis that is perpendicular to the second portion of the area of active semiconductor material. The semiconductor device further includes a compensation feature extending from the first edge of the first portion of the area of active semiconductor material less than an amount to provide an electrical contact structure on the compensation feature and positioned laterally further away from the corner than the overlying transistor control electrode, the compensation feature being positioned from the corner by a dimension that is within 0.4 to 0.6 of the wavelength of light used to image features of the semiconductor device.

In another embodiment, a method of providing a semiconductor device includes providing an area of active semiconductor material comprising a first portion with a first edge and a second portion with a second edge, the first edge and the second edge intersecting at a desired right angle to form a corner. The method further includes providing an overlying transistor control electrode overlying the first portion of the area of active semiconductor material and comprising a major dimension including a major axis that is perpendicular to the first edge of the first portion of the area of active semiconductor material and comprising a minor dimension including a minor axis that is perpendicular to the second portion of the area of active semiconductor material. The method still further includes providing a compensation feature extending from the first edge of the first portion of the area of active semiconductor material less than an amount to provide an electrical contact structure on the compensation feature and positioned laterally further away from the corner than the overlying transistor control electrode, the compensation feature being positioned from the corner by a dimension that is within 0.4 to 0.6 of the wavelength of light used to image features of the semiconductor device.

According to another embodiment, the method further includes extending the area of active semiconductor material into a portion of the corner due to optical distortion and modifying effects of the optical distortion with the compensation feature so that underlying the overlying transistor electrode the active semiconductor material extends from the first edge of the area of active semiconductor material with a contour having less active semiconductor material in an interior portion underlying the control electrode than at an edge boundary underlying the control electrode. The method further comprises using the compensation feature to modify the optical distortion by creating constructive light interference to result in a least amount of active semiconductor material that underlies the transistor control electrode being substantially in a middle of the overlying transistor control electrode.

According to yet another embodiment, the method further comprises providing a source electrode and a drain electrode. The source electrode is contained within the active semiconductor material adjacent a first side of the transistor control electrode along the major axis. The drain electrode is contained within the active semiconductor material adjacent a second side of the transistor control electrode along the major axis and opposite the first side of the transistor control electrode. The method still further comprises providing the compensation feature as a continuous part of one of the source electrode or the drain electrode within the area of active semiconductor material, the compensation feature not providing a conduction path for source or drain electrons.

According to another embodiment, the method further includes providing the compensation feature as a feature having a nonlinear edge due to effects of optical distortion. In another embodiment, the method further comprises forming a portion of the area of active semiconductor material in the corner on either side of the transistor control electrode due to optical distortion, the active semiconductor material increasing in amount on either side of the transistor control electrode as a function of distance from the transistor control electrode.

In another embodiment, a semiconductor device includes an area of active semiconductor material, a compensation feature, and a transistor gate. The area of active semiconductor material comprises a first portion along a first axis intersecting with a second portion along a second axis to form a concave corner due to optical distortion. The compensation feature comprises a nonlinear shape, the optical compensation feature reducing effects of the optical distortion and positioned along an edge of the first portion of the area of active semiconductor material at a distance from the concave corner that is within a range of 0.4 to 0.6 multiplied by a wavelength of light used to image features of the semiconductor device, the nonlinear compensation feature having an area that is less than an amount to accommodate an electrical contact structure. The transistor gate overlies the first portion of the active semiconductor material and is closer to the concave corner than is the compensation feature in a direction along the first axis. An amount of active semiconductor material within the concave corner at an edge of the first portion that is covered by the transistor gate is less than in each side area not covered by the transistor gate within the concave corner.

In a further embodiment, the area of active semiconductor material extends from the edge of the first portion thereof from the effects of the optical distortion and increases in amount on either side of the transistor gate as a function of distance from the transistor gate. In yet another embodiment, an amount of active semiconductor material extending from the edge of the first portion thereof is less in a central region of the first portion within the concave corner that is covered by the transistor gate than in periphery regions within the concave corner that is covered by the transistor gate.

In another embodiment, the semiconductor device includes an area of active semiconductor material, a compensation feature, and a transistor gate. The area of active semiconductor material has a first portion along a first axis intersecting with a second portion along a second axis to form a concave corner due to optical distortion. The compensation feature has a nonlinear shape, the optical compensation feature reducing effects of the optical distortion and positioned along an edge of the first portion of the area of active semiconductor material at a distance from the concave corner that is within a range of 0.4 to 0.6 multiplied by a wavelength of light used to image features of the semiconductor device, the nonlinear compensation feature having an area that is less than an amount to accommodate an electrical contact structure. The transistor gate overlies the first portion of the active semiconductor material and is closer to the concave corner than is the compensation feature in a direction along the first axis, the transistor gate having first and second opposite sides that define a gate length dimension, a gate width dimension at each of the first and second opposite sides being greater than at least one gate width dimension inside of the first and second opposite sides. In addition, the area of active semiconductor material extends from the edge of the first portion thereof on either side of the transistor gate from effects of the optical distortion in an amount that increases as a function of distance from the transistor gate. Furthermore, the gate width dimension at each of the first and second opposite side is greater than all gate width dimensions inside of the first and second opposite sides.

In a still further embodiment, the semiconductor device further includes a source electrode and a drain electrode. The source electrode is contained within the area of active semiconductor material adjacent a first side of the transistor gate. The drain electrode is contained within the area of active semiconductor material adjacent a second side of the transistor gate that is opposite the first side of the transistor gate, wherein the compensation feature is formed as a continuous part of one of the source electrode or the drain electrode within the area of active semiconductor material but does not provide a conduction path for source or drain electrons.

The terms “front,” “back,” “top,” “bottom,” “over,” “under” and the like in the description and in the claims, if any, are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

Although the invention is described herein with reference to specific embodiments, various modifications and changes can be made without departing from the scope of the present invention as set forth in the claims below. Accordingly, the specification and figures are to be regarded in an illustrative rather than a restrictive sense, and all such modifications are intended to be included within the scope of the present invention. Any benefits, advantages, or solutions to problems that are described herein with regard to specific embodiments are not intended to be construed as a critical, required, or essential feature or element of any or all the claims.

The term “coupled,” as used herein, is not intended to be limited to a direct coupling or a mechanical coupling.

Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles.

Unless stated otherwise, terms such as “first” and “second” are used to arbitrarily distinguish between the elements such terms describe. Thus, these terms are not necessarily intended to indicate temporal or other prioritization of such elements.

What is claimed is:

1. A semiconductor device comprising:
an area of active semiconductor material comprising a first portion with a first edge and a second portion with a second edge, the first edge and the second edge intersecting at a desired right angle to form a corner;
an overlying transistor control electrode overlying the first portion of the area of active semiconductor material and comprising a major dimension including a major axis that is perpendicular to the first edge of the first portion of the area of active semiconductor material and comprising a minor dimension including a minor axis that is perpendicular to the second portion of the area of active semiconductor material; and
a compensation feature extending from the first edge of the first portion of the area of active semiconductor material less than an amount to provide an electrical contact structure on the compensation feature and positioned laterally further away from the corner than the overlying transistor control electrode, the compensation feature being positioned from the corner by a dimension that is within 0.4 to 0.6 of the wavelength of light used to image features of the semiconductor device.

2. The semiconductor device of claim 1 wherein the area of active semiconductor material extends into a portion of the corner and underlies the overlying transistor control electrode, the active semiconductor material extending from the first edge of the area of active semiconductor material with a contour having less active semiconductor material in an interior portion underlying the control electrode than at an edge boundary underlying the control electrode.

3. The semiconductor device of claim 2 wherein the interior portion underlying the control electrode comprising a least amount of active semiconductor material is underlying substantially a middle of the overlying transistor control electrode and along the first edge.

4. The semiconductor device of claim 1 further comprising:
a source electrode contained within the active semiconductor material adjacent a first side of the transistor control electrode along the major axis; and
a drain electrode contained within the active semiconductor material adjacent a second side of the transistor control electrode along the major axis and that is opposite the first side of the transistor control electrode,
wherein the compensation feature is formed as a continuous part of one of the source electrode or the drain electrode within the area of active semiconductor material but does not provide a conduction path for source or drain electrons.

5. The semiconductor device of claim 1 wherein the compensation feature has a nonlinear edge due to optical distortion when forming the compensation feature.

6. The semiconductor device of claim 1 wherein a portion of the area of active semiconductor material extends into the corner on either side of the transistor control electrode due to optical distortion, the active semiconductor material increasing in amount on either side of the transistor control electrode as a function of distance from the transistor control electrode.

7. A method of providing a semiconductor device comprising:
providing an area of active semiconductor material comprising a first portion with a first edge and a second portion with a second edge, the first edge and the second edge intersecting at a desired right angle to form a corner;
providing an overlying transistor control electrode overlying the first portion of the area of active semiconductor material and comprising a major dimension including a major axis that is perpendicular to the first edge of the first portion of the area of active semiconductor material and comprising a minor dimension including a minor axis that is perpendicular to the second portion of the area of active semiconductor material; and
providing a compensation feature extending from the first edge of the first portion of the area of active semiconductor material less than an amount to provide an electrical contact structure on the compensation feature and positioned laterally further away from the corner than the overlying transistor control electrode, the compensation feature being positioned from the corner by a dimension that is within 0.4 to 0.6 of the wavelength of light used to image features of the semiconductor device.

8. The method of claim 7 further comprising
extending the area of active semiconductor material into a portion of the corner due to optical distortion; and
modifying effects of the optical distortion with the compensation feature so that underlying the overlying transistor electrode the active semiconductor material extends from the first edge of the area of active semiconductor material with a contour having less active semiconductor material in an interior portion underlying the control electrode than at an edge boundary underlying the control electrode.

9. The method of claim 8 further comprising:
using the compensation feature to modify the optical distortion by creating constructive light interference to result in a least amount of active semiconductor material that underlies the transistor control electrode being substantially in a middle of the overlying transistor control electrode.

10. The method of claim 7 further comprising:
providing a source electrode contained within the active semiconductor material adjacent a first side of the transistor control electrode along the major axis;
providing a drain electrode contained within the active semiconductor material adjacent a second side of the transistor control electrode along the major axis and opposite the first side of the transistor control electrode; and
providing the compensation feature as a continuous part of one of the source electrode or the drain electrode within the area of active semiconductor material, the compensation feature not providing a conduction path for source or drain electrons.

11. The method of claim 7 further comprising:
providing the compensation feature as a feature having a nonlinear edge due to effects of optical distortion.

12. The method of claim 7 further comprising:
forming a portion of the area of active semiconductor material in the corner on either side of the transistor control electrode due to optical distortion, the active semiconductor material increasing in amount on either side of the transistor control electrode as a function of distance from the transistor control electrode.

13. A semiconductor device comprising:
an area of active semiconductor material having a first portion along a first axis intersecting with a second portion along a second axis to form a concave corner due to optical distortion;
a compensation feature having a nonlinear shape, the compensation feature reducing effects of the optical distortion and positioned along an edge of the first portion of the area of active semiconductor material at a distance from the concave corner that is within a range of 0.4 to 0.6 multiplied by a wavelength of light used to image features of the semiconductor device, the nonlinear compensation feature having an area that is less than an amount to accommodate an electrical contact structure; and
a transistor gate overlying the first portion of the active semiconductor material and being closer to the concave corner than is the compensation feature in a direction along the first axis, an amount of active semiconductor material within the concave corner at an edge of the first portion that is covered by the transistor gate is less than in each side area not covered by the transistor gate within the concave corner.

14. The semiconductor device of claim 13 wherein the area of active semiconductor material extending from the edge of the first portion thereof from the effects of the optical distortion increases in amount on either side of the transistor gate as a function of distance from the transistor gate.

15. The semiconductor device of claim 13 wherein an amount of active semiconductor material extending from the edge of the first portion thereof is less in a central region of the first portion within the concave corner that is covered by the transistor gate than in periphery regions within the concave corner that is covered by the transistor gate.

16. The semiconductor device of claim 13 further comprising:
a source electrode contained within the area of active semiconductor material adjacent a first side of the transistor gate; and
a drain electrode contained within the area of active semiconductor material adjacent a second side of the transistor gate that is opposite the first side of the transistor gate,
wherein the compensation feature is formed as a continuous part of one of the source electrode or the drain electrode within the area of active semiconductor material but does not provide a conduction path for source or drain electrons.

17. A semiconductor device comprising:
an area of active semiconductor material having a first portion along a first axis intersecting with a second portion along a second axis to form a concave corner due to optical distortion;
a compensation feature having a nonlinear shape, the compensation feature reducing effects of the optical distortion and positioned along an edge of the first portion of the area of active semiconductor material at a distance from the concave corner that is within a range of 0.4 to 0.6 multiplied by a wavelength of light used to image features of the semiconductor device, the nonlinear compensation feature having an area that is less than an amount to accommodate an electrical contact structure; and
a transistor gate overlying the first portion of the active semiconductor material and being closer to the concave corner than is the compensation feature in a direction along the first axis, the transistor gate having first and second opposite sides that define a gate length dimension, a gate width dimension at each of the first and second opposite sides being greater than at least one gate width dimension inside of the first and second opposite sides.

18. The semiconductor device of claim 17 wherein the area of active semiconductor material extends from the edge of the first portion thereof on either side of the transistor gate from effects of the optical distortion in an amount that increases as a function of distance from the transistor gate.

19. The semiconductor device of claim 17 wherein the gate width dimension at each of the first and second opposite side is greater than all gate width dimensions inside of the first and second opposite sides.

20. The semiconductor device of claim 17 further comprising:
a source electrode contained within the area of active semiconductor material adjacent the first side of the transistor gate; and
a drain electrode contained within the area of active semiconductor material adjacent the second side of the transistor gate,
wherein the compensation feature is formed as a continuous part of one of the source electrode or the drain electrode within the area of active semiconductor material but does not provide a conduction path for source or drain electrons.
